(19) United States
(12) Patent Application Publication
(10) Pub. No.: US 2014/0316596 A1
(43) Pub. Date: Oct. 23, 2014

(54) INFORMATION PROCESSING METHOD AND INFORMATION PROCESSING SYSTEM

(71) Applicant: FUJITSU LIMITED, Kawasaki-shi (JP)

(72) Inventors: Tamon SUWA, Kawasaki (JP); Masaki Kazama, Kawasaki (JP)

(73) Assignee: FUJITSU LIMITED, Kawasaki-shi (JP)

(21) Appl. No.: 14/191,919

(22) Filed: Feb. 27, 2014

(30) Foreign Application Priority Data
Apr. 19, 2013 (JP) 2013-088355

(51) Int. Cl. G01R 21/133

(52) U.S. Cl. CPC G01R 21/1331
USPC 700/291

(57) ABSTRACT

An information processing method includes: calculating, by a computer, a time differential of internal energy that corresponds to a coefficient and is based on radiative cooling, the coefficient corresponding to a degree of exposure of each particle in a collection of particles to a surface of a continuum represented by the collection of the particles; and calculating, by the computer, the internal energy after a unit time based on the time differential of the internal energy.

### CROSS-REFERENCE TO RELATED APPLICATION

This application is based upon and claims the benefit of priority of the prior Japanese Patent Application No. 2013-088355, filed on Apr. 19, 2013, the entire contents of which are incorporated herein by reference.

### FIELD

The embodiments discussed herein are related to an information processing method and an information processing system.

### BACKGROUND

The flow of fluid in fluid analysis, such as water or air, and the behavior of an elastic body in elastic body analysis, such as compressed rubber, are analyzed by using numerical calculation..

Related technologies are disclosed in Non-Patent Document 1: Paul W. Cleary, “Extension of SPH to predict feeding, freezing and defect creation in low pressure die casting”, Applied Mathematical Modelling, vol. 34, pp. 3189-3201, 2010, Non-Patent Document 2: Paul W. Cleary, “Modelling confined multi-material heat and mass flows using SPH”, Applied Mathematical Modelling, vol. 22, pp. 981-993, 1998, Japanese Laid-open Patent Publication No. 2002-137272, Japanese Laid-open Patent Publication No. 2012-150673, and International Publication Pamphlet No. WO2012/111082.

### SUMMARY

According to an aspect of the embodiment, an information processing method includes: calculating, by a computer, a time differential of internal energy that corresponds to a coefficient and is based on radiative cooling, the coefficient corresponding to a degree of exposure of each particle in a collection of particles to a surface of a continuum represented by the collection of the particles; and calculating, by the computer, the internal energy after a unit time based on the time differential of the internal energy.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 illustrates an example of a continuum represented by a collection of particles;

FIG. 2 illustrates an example of an influence domain;

FIG. 3 illustrates an example of a solidification process;

FIG. 4 illustrates an example of a parameter;

FIG. 5 illustrates an example of a state of particles;

FIG. 6 illustrates an example of a state of particles;

FIG. 7 illustrates an example of a state of particles;

FIG. 8 illustrates an example of a relationship between an arrangement of particles, a normalized number density, and a variable of a polynomial;

FIG. 9 illustrates an example of a relationship between Qₐ and gₐ(Qₐ);

FIG. 10 illustrates an example of a functional block of an information processing apparatus;

FIG. 11 illustrates an example of a process;

FIG. 12 illustrates an example of a process; and

FIG. 13 illustrates an example of a computer.

### DESCRIPTION OF EMBODIMENTS

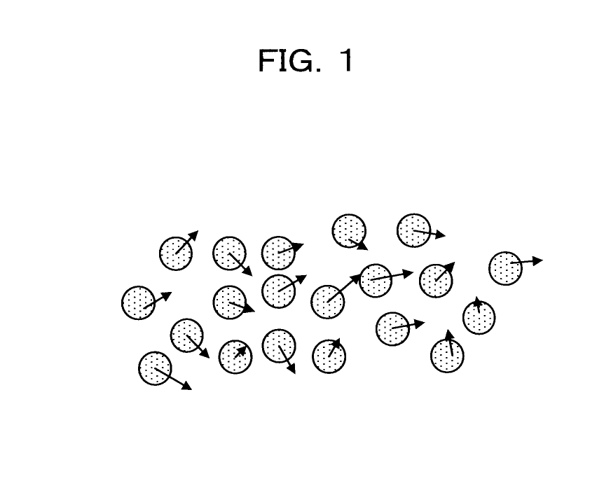

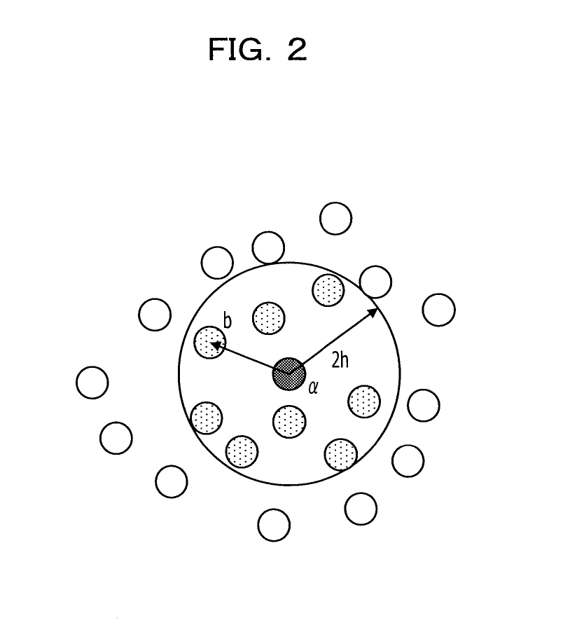

FIG. 1 illustrates an example of a continuum represented by a collection of particles. A method of representing the continuum by the distribution of the particles is illustrated in FIG. 1 (such methods are hereinafter referred to as particle methods). The particle methods include, for example, a Smoothed Particle Hydrodynamics (SPH) method or a Moving Particle Semi-implicit (MPS) method. FIG. 2 illustrates an example of an influence domain. Referring to FIG. 2, an area is set in advance for a particle a (this area is hereinafter referred to as an “influence domain”). For example, the area may be a circle defined by a radius 2 h (h denotes a parameter representing the size of the range of impact of the particle (hereinafter referred to as an influence radius)). Interaction only from another target particle b existing within the influence domain is calculated to analyze the motion of an object.

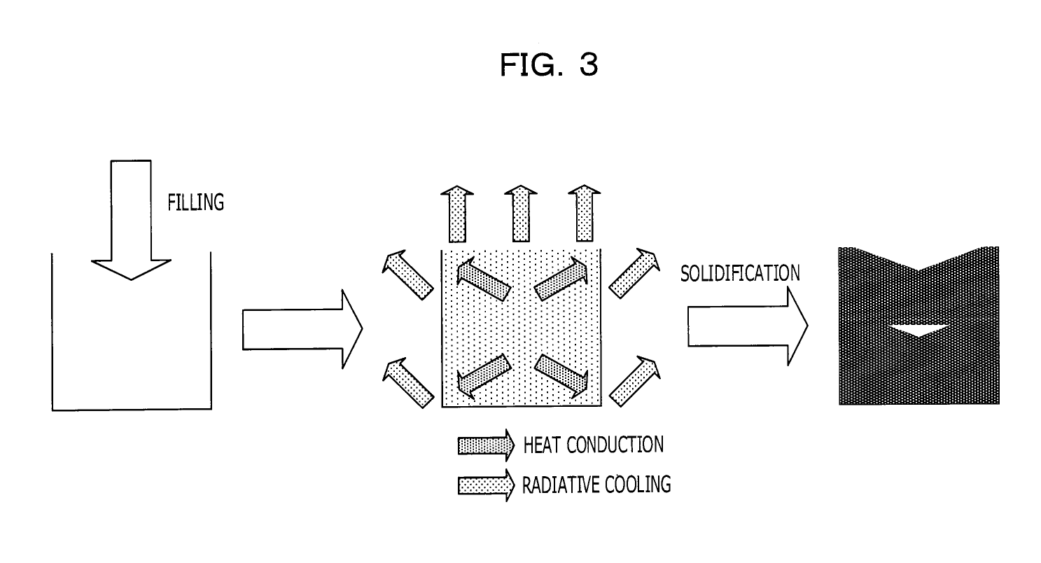

For example, in metalworking including casting and forging, a change in volume is involved in a solidification process in which metal that is cooled to be solidified is mixed with liquid metal. FIG. 3 illustrates an example of a solidification process. For example, as illustrated in FIG. 3, upon filling a container with the liquid metal, the heat of the liquid metal in the container is externally transferred by heat conduction and radiative cooling occurs on the surface of the container and the surface of the liquid metal on an upper face of the container. The progress of such a phenomenon causes the solidification of the liquid metal. In an example on the right side in FIG. 3, a cavity occurs in part of the liquid metal due to a reduction in volume caused by the solidification.

The particle method may be used in casting simulation and forging simulation based on, for example, the simplicity of the processing of a free surface, the parallel performance when parallel computing is performed at multiple computing nodes, and the easiness of coupling calculation with solid.

The MPS method may be used in flux analysis of resin.

In the SPH method, the physical quantity of multiple particles is smoothed by using a weighting function called a Kernel function to discretize basic equations. For example, in order to process the flow of molten metal in the casting, an equation of continuity, an equation of motion, and an energy equation are discretized in the following manner:

$$\begin{matrix} \frac{d {ρ}_{a}}{d t} = {\sum }_{b} {m}_{b} {v}_{ab} \cdot \frac{\partial W ( {r}_{ab} , h )}{\partial {r}_{a}} & ( 1 ) \\ \frac{d {v}_{a}}{d t} = - {\sum }_{b} {m}_{b} [ ( \frac{{P}_{b}}{{ρ}_{b}^{2}} + \frac{{P}_{a}}{{ρ}_{a}^{2}} ) - \frac{ξ}{{ρ}_{a} {ρ}_{b}} \frac{4 {μ}_{a} {μ}_{b}}{( {μ}_{a} + {μ}_{b} )} \frac{{r}_{ab} \cdot {v}_{ab}}{{r}_{ab}^{2} + {η}^{2}} ] \frac{\partial W ( {r}_{ab} , h )}{\partial {r}_{a}} + g & ( 2 ) \\ \frac{d {u}_{a}}{d t} = - {\sum }_{b} {m}_{b} [ \frac{1}{{ρ}_{a} {ρ}_{b}} \frac{4 {κ}_{a} {κ}_{b}}{{κ}_{a} + {κ}_{b} r} \frac{{T}_{ab} {r}_{ab}}{{r}_{ab}^{2} + {η}^{2}} ] \cdot \frac{\partial W ( {r}_{ab} , h )}{\partial {r}_{a}} & ( 3 )\end{matrix}$$

Each subscript represents an index of each particle. In the above equations, ρₐ denotes the density of the particle a, mₐ denotes the mass of the particle a, vₐ denotes the velocity vector of the particle a, rₐ denotes the position vector of the particle a, Pₐ denotes the pressure of the particle a, μₐ denotes the viscosity coefficient of the particle a, uₐ denotes the internal energy per unit mass of the particle a, Tₐ denotes the temperature of the particle a, and κₐ denotes the heat conduction coefficient of the particle a.

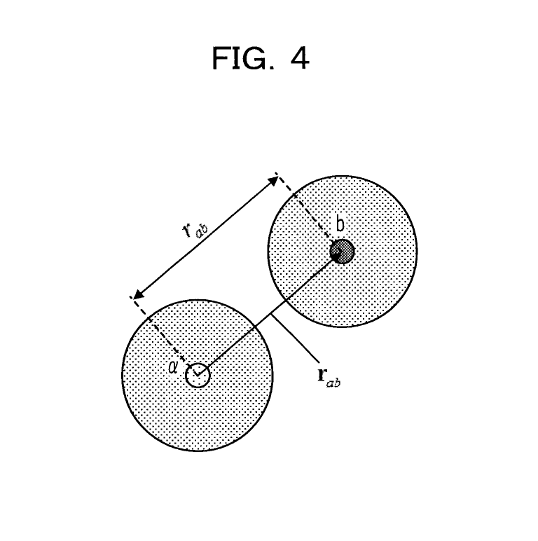

FIG. 4 illustrates an example of a variables representing relative position. The following relationship is also established:

v_{ab}=vₐ−v_{b}

r_{ab} (bold)=rₐ−r_{b}

r_{ab} (italic)=|r_{ab} (bold)|

T_{ab}=Tₐ−T_{b}

In the above equations, η denotes a numerical parameter for suppressing the divergence of a denominator, g denotes an acceleration of gravity, and denotes a numerical parameter indicating the effect of viscosity. ξ=4.96333 may be used. W denotes the Kernel function and is used to compose a continuous field from the distribution of the particles. For example, W may denote a cubic spline function.

The pressure may be calculated by using the following state equation:

$${P}_{a} = {P}_{0} [ {( \frac{{ρ}_{a}}{{ρ}_{0}} )}^{γ} - 1 ] \qquad ( 5 )$$

In the above state equation, P₀ denotes a reference pressure of fluid, ρ₀ denotes a reference density, and y denotes an adiabatic index. γ=1 or γ=7 may be used.

The right-hand side of the equation (3), which is the energy equation, is a term based on the heat conduction. When the effect of conversion of the kinetic energy into the internal energy due to adiabatic expansion, compression, and viscous dissipation is considered, the following equation may be added to the equation (3):

$${\frac{d {u}_{a}}{d t} \vert}_{Motion} = {\sum }_{b} \frac{{m}_{b} {v}_{ab}}{2} [ ( \frac{{P}_{b}}{{ρ}_{b}^{2}} + \frac{{P}_{a}}{{ρ}_{a}^{2}} ) - \frac{ξ}{{ρ}_{a} {ρ}_{b}} \frac{4 {μ}_{a} {μ}_{b}}{( {μ}_{a} + {μ}_{b} )} \frac{{r}_{ab} \cdot {v}_{ab}}{{r}_{ab}^{2} + {η}^{2}} ] \cdot \frac{\partial W ( {r}_{ab} , h )}{\partial {r}_{a}} \qquad ( 6 )$$

In the variation in temperature of an object in the casting process or the like, the variation in temperature caused by heat radiation from the surface of the object may be considered, in addition to the terms of the heat conduction, the adiabatic expansion, the compression, and the viscous dissipation, in the example illustrated in FIG. 3. For example, Stefan-Boltmann's law may be considered. The Stefan-Boltmann's law is a physical law in which the electromagnetic energy emitted from the surface of a black body per unit area and per unit time is proportional to the biquadrate of a thermodynamic temperature T of the black body.

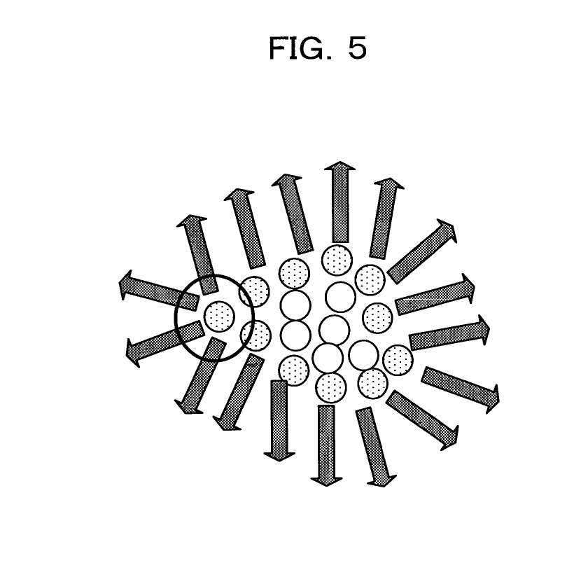

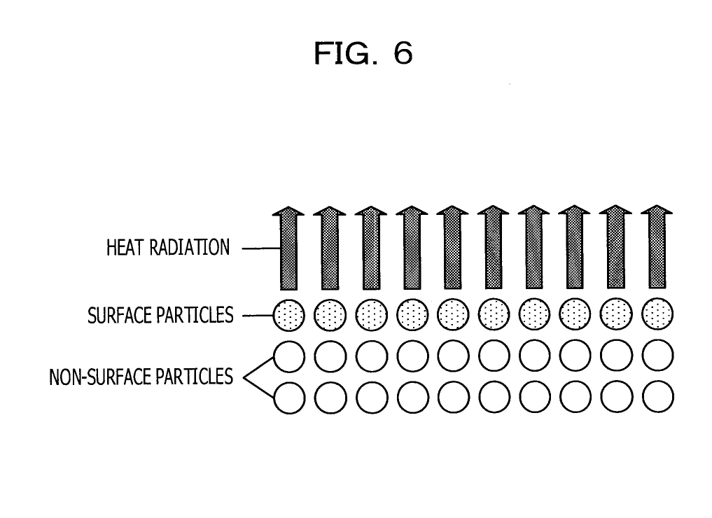

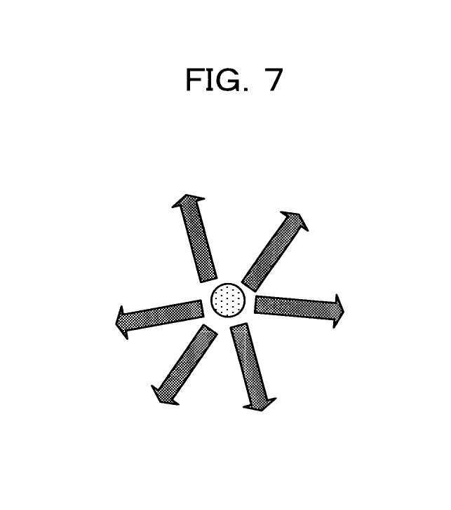

In the radiative cooling, the internal energy may not be calculated in consideration of the state of particles. FIG. 5, FIG. 6, and FIG. 7 illustrate an example of a state of particles. For example, the amount of radiation at a pointed top (a part indicated by a circle) illustrated in FIG. 5 may be greater than the amount of radiation of the particles on a plain face in a case in which the surface of the object is a plane illustrated in FIG. 6, and the amount of energy that is lost per unit time at the pointed top illustrated in FIG. 5 may be greater than that of the particles on the plain face. The particles on a plain face are called surface particles and the particles inside the surface are called non-surface particles or internal particles. Such differences may not be reflected in the numerical calculation. For example, when a droplet splatters to form isolated particles as in the example illustrated in FIG. 7, the radiative cooling may occur effectively because the heat radiation is performed toward the whole space. Such an effect may not be considered in the numerical calculation.

For example, the time differential of the internal energy may be calculated for all the particles according to the following equation:

$${\frac{d {u}_{a}}{d t} \vert}_{Radiation} = - {g}_{a} α \frac{1}{{m}_{a}} σ {{T}_{a}^{4} ( \frac{{m}_{a}}{{ρ}_{a}} )}^{1 - \frac{1}{d}} \qquad ( 8 )$$

In the above equation, gₐ denotes a coefficient used to quantify the degree of exposure of the particle a to the surface of the object (the surface of the continuum). The coefficient gₐ may be a continuous function to perform correction so that (A) the radiative cooling does not occur when the particles exist in the continuum, (B) the radiative cooling occurs from one face, among the six faces of a parallelepiped which has a volume equivalent to that of the particles and each side of which has the same length, when the particles are uniformly distributed on the plain face, and (C) the radiative cooling occurs in the same manner as in a sphere having a volume equivalent to that of the particles when the particles are isolated. The portions other than the coefficient gₐ in the equation (8) indicate the Stefan-Boltrmann's law. In the equation (8), σ denotes a Stefan-Boltrmann constant that does not depend on the substance, a denotes a coefficient representing the shift of the object from the black body (hereinafter referred to as emissivity), and d denotes a space dimension. For example, d may be equal to one, two, or three. In the equation (8), (mₐ/ρₐ)^{1-(1/d)} denotes the surface area of the particle a. “The one face, among the six faces of a parallelepiped which has a volume equivalent to that of the particles and each side of which has the same length”, may have the same area as that of one face, among the six faces of a cube having a volume equivalent to that of the particles. Instead of the condition (B), “the radiative cooling occurs from one face, on the assumption that the particle is a polyhedron or a hemisphere having a volume equivalent to that of the particle depending on the surface shape” may be adopted.

The coefficient gₐ may be represented as a function of a normalized number density illustrated below:

$${s}_{a} = {\sum }_{b} \frac{{m}_{b}}{{ρ}_{b}} W ( {r}_{ab} , h )$$

The normalized number density has a value closer to one if sufficient other particles exist within the influence domain of the particle a and has a lower value if a smaller number of particles exist within the range of impact.

The Kernel function W (r, h) may be, for example, a quintic spline function illustrated below:

$$W ( r , h ) = \{ \begin{matrix}{{α}_{d} ( 1 - \frac{q}{2} )}^{4} ( 2 q + 1 ) & ( 0 \leq q \leq 2 ) \\ 0 & ( 2 < q )\end{matrix} \qquad ( 4 )$$

In the above equation, a_{d} is a normalization factor and q=r/h.

The normalized number density sₐ has a value of one in the object and has the following value in the isolated particles:

$$\frac{{m}_{a}}{{ρ}_{a}} W ( 0 , h ) = {s}_{min , a}$$

On a plain face taken as a plane, the normalized number density sₐ may be defined so as to have a value of “(1+s_{min,a})/2”.

Although the coefficient gₐ that meets the above conditions is not uniquely determined, the conditions (A) to (C) are met, for example, if the following polynomial is adopted.

gₐ(Qₐ)=Aₐ(a_{2,a}Qₐ²+a_{3,a}Qₐ³) (9)

Symbols have the following meanings:

$${Q}_{a} = \frac{( 1 - {s}_{a} )}{( 1 - {s}_{min , a} )}$$

$${A}_{a} = {{S}_{1 , a} ( \frac{{m}_{a}}{{ρ}_{a}} )}^{- 1 + \frac{1}{d}}$$

$${S}_{1 , a} = 4 π {r}_{a}^{2}$$

$${r}_{a} = {( \frac{3}{4 π} \frac{{m}_{a}}{{ρ}_{a}} )}^{\frac{1}{3}}$$

$${a}_{2 , a} = \frac{8}{{A}_{a}} - 1$$

$${a}_{3 , a} = 2 - \frac{8}{{A}_{a}}$$

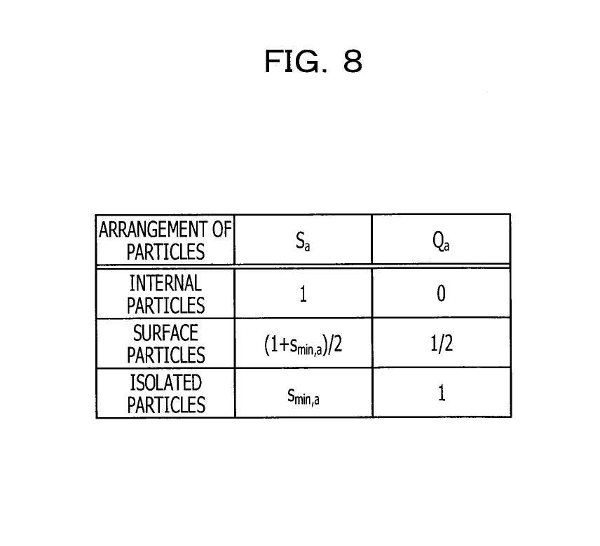

FIG. 8 illustrates an example of a relationship between an arrangement of particles, a normalized number density, and a variable of a polynomial. The relationship between the arrangement of particles, the value of sₐ, and the value of Qₐ when Qₐ=(1−sₐ)/(1−_{smin,a}) is defined as illustrated in FIG. 8. For example, in the case of the internal particles (=the non-surface particles), sₐ may be equal to one (sₐ=1) and Qₐ may be equal to zero (Qₐ=0). In the case of the surface particles, sₐ may be equal to (1+_{smin,a})/2 (sₐ=(1+s_{min,a})/2) and Qₐ may be equal to ½ (Qₐ=½). In the case of the isolated particles, sₐ may be equal to s_{min,a} (sₐ=s_{min,a}) and Qₐ may be equal to one (Qₐ=1).

The conditions to be met by the coefficient gₐ are indicated in the following manner as the conditions to be met by the polynomial gₐ(Qₐ):

(A) The radiative cooling does not occur when the particles exist in the object. This is equivalent to gₐ(0)=0. This is because no internal energy is lost by the radiative cooling if gₐ(0)=0 when the internal particles: Qₐ=0 and, thus, the radiative cooling does not occur.

(B) The radiative cooling occurs from one face of a cube having a volume equivalent to that of the particles, when the particles are uniformly distributed on the plain face. This is equivalent to gₐ (½)=1. This is because the internal energy lost by the radiative cooling if gₐ(½)=1 when the surface particles: Qₐ=½ coincides with the quantity calculated according to the Stefan-Boltzmann's law (the value of the equation resulting from exclusion of gₐ in the equation (8)).

(C) The radiative cooling occurs in the same manner as in a sphere having a volume equivalent to that of the particles when the particles are isolated. This condition is represented by the following equation:

$${g}_{a} ( 1 ) {( \frac{{m}_{a}}{{ρ}_{a}} )}^{1 - \frac{1}{d}} = {S}_{1 , a}$$

In the above equation, S_{1,a} is defined in the above manner and represents the surface area when the particle a is taken as a sphere and (mₐ/ρₐ)¹⁻⁽1/d) denotes the surface area of one particle a in the arrangement in which the particles are uniformly distributed on the plane face. As for the isolated particles, the condition that the radiative cooling occurs in the same manner as in a sphere having a volume equivalent to that of the particles is met if the result of multiplication of (mₐ/ρₐ)^{1-(1/d)} by the coefficient gₐ coincides with the surface area when the particle a is taken as the sphere.

In the numerical calculation, the value of Qₐ may be slightly fluctuated around zero for the internal particles due to a slight shift of the arrangement of the particles. In order to reduce the responsive variation of the correction coefficient of the radiative cooling due to the fluctuation, a condition represented by the following equation may be added:

$$\frac{d {g}_{a}}{d {Q}_{a}} ( 0 ) = 0$$

The polynomial that meets the following four equations and that has the lowest order is the equation (9):

$${g}_{a} ( 0 ) = 0$$

$${g}_{a} ( \frac{1}{2} ) = 1$$

$${g}_{a} ( 1 ) {( \frac{{m}_{a}}{{ρ}_{a}} )}^{1 - \frac{1}{d}} = {S}_{1 , a}$$

$$\frac{d {g}_{a}}{d {Q}_{a}} ( 0 ) = 0$$

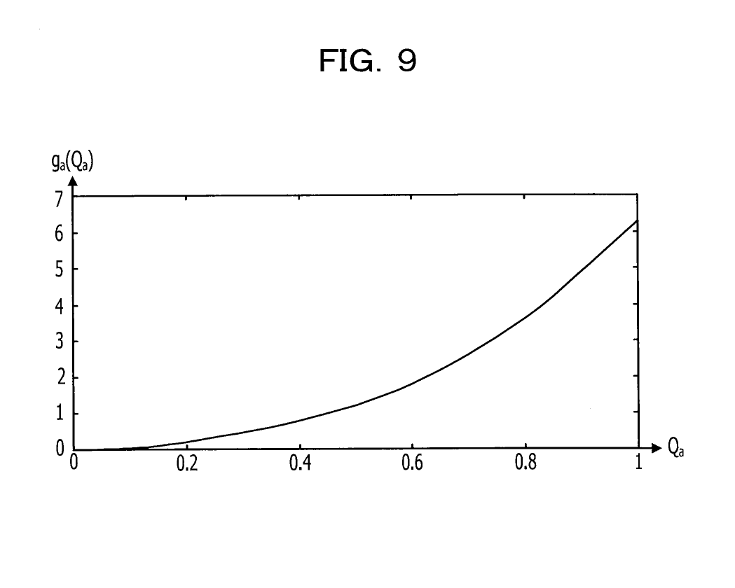

FIG. 9 illustrates an example of a relationship between Qₐ and gₐ(Qₐ). Instead of the polynomial having the lowest order, a polynomial having a higher order may be adopted as long as the polynomial is a smooth function illustrated in FIG. 9.

The relationship between Qₐ and gₐ(Qₐ) when Aₐ3^{2/3}(4π)^{1/3} in three dimensions is illustrated in FIG. 9.

Referring to FIG. 9, gₐ(Qₐ) smoothly increases around Qₐ=0 and gₐ(Qₐ)=1 when Qₐ=½. When Qₐ is greater than ½, gₐ(Qₐ) sharply increases.

The adoption of the coefficient gₐ may cause the state of the particles to be appropriately reflected in the reduction in the internal energy due to the radiative cooling. The coefficient gₐ is a continuous function represented by the polynomial having the normalized number density as a variable and the state of the particles may be reflected in a continuous manner, instead of a branch in the processing flow.

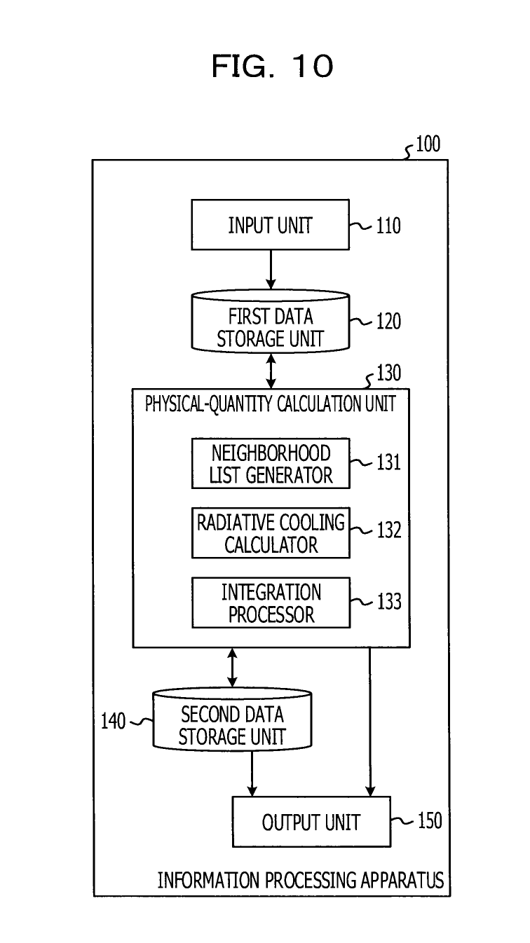

FIG. 10 illustrates an example of a functional block of an information processing apparatus. An information processing apparatus 100 to perform simulation including the radiative cooling described above is illustrated in FIG. 10.

Referring to FIG. 10, the information processing apparatus 100 includes an input unit 110, a first data storage unit 120, a physical-quantity calculation unit 130, a second data storage unit 140, and an output unit 150.

The input unit 110 acquires data from another computer coupled to the information processing apparatus 100 via, for example, a network or accepts data input by a user to store the acquired or accepted data in the first data storage unit 120 as data to be processed.

The input data includes data about the particles of a continuum to be subjected to the numerical calculation and data about fixed boundary elements that set, for example, the boundary condition concerning the motion of the particles of the continuum. The particles of the continuum may result from modeling of fluid. The data about the particles of the continuum includes, for example, the initial center position coordinate, the initial velocity, the influence radius, the density, the mass, or the viscosity. The fixed boundary elements may result from modeling of plane elements that result from division of the surface or the like of, for example, a casting mold into micro portions. The data about the fixed boundary elements includes, for example, the center coordinate of each boundary element resulting from modeling of the entire boundary as a collection of micro discs, the normal vector of each plane element, and the area of each plane element. The entire boundary may be represented as a collection of polygons and the position coordinates of multiple vertexes may be set for each boundary element.

The physical-quantity calculation unit 130 includes a neighborhood list generator 131, a radiative cooling calculator 132, and an integration processor 133. The physical-quantity calculation unit 130 calculates the physical quantity of each particle every unit time. The neighborhood list generator 131 generates a list of other particles included in the influence domain of each particle every unit time and stores the generated list in the second data storage unit 140. The radiative cooling calculator 132 calculates the time differential of the internal energy based on the radiative cooling for each particle every unit time and stores the calculated time differential in the second data storage unit 140. The integration processor 133 performs time integration on, for example, the acceleration, the velocity, the time differential of the density, or the time differential of the internal energy calculated for each particle to calculate the physical quantity after one unit time, such as the velocity, the position, the density, or the internal energy, and stores the calculated physical quantity in the second data storage unit 140.

The output unit 150 generates output data by using the physical quantity for every unit time, which is stored in the second data storage unit 140, and outputs the generated output data to another computer or to an output apparatus, such as a printer apparatus or a display apparatus.

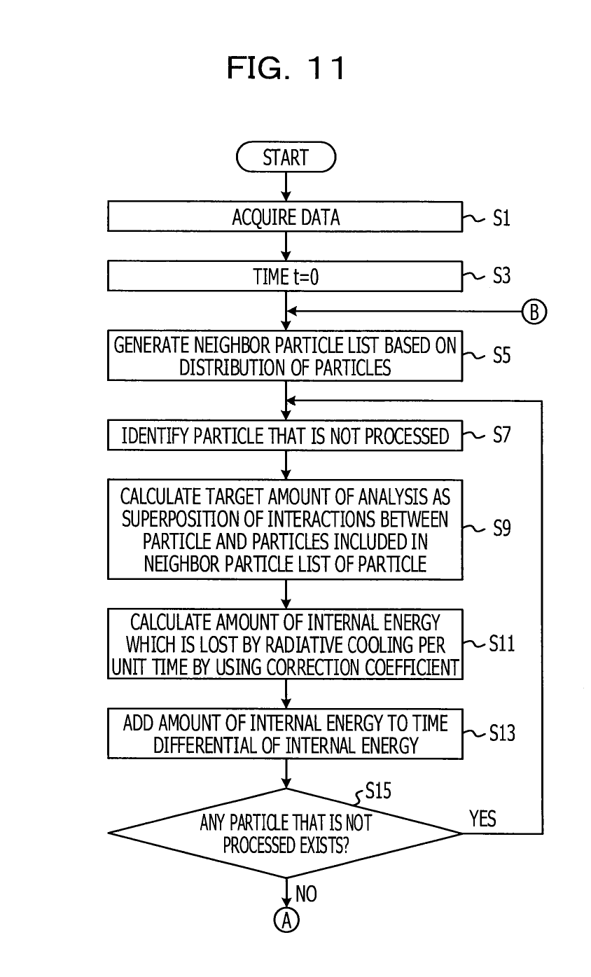

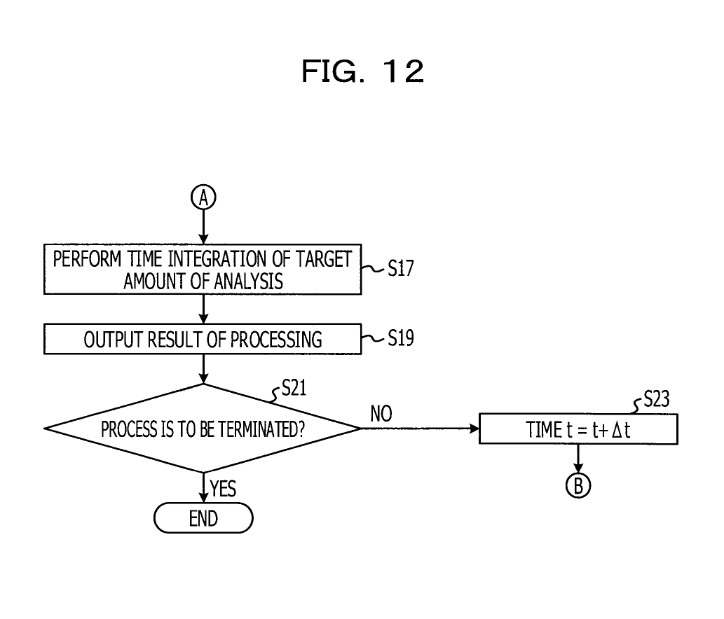

FIG. 11 and FIG. 12 illustrate an example of a process. The process performed by the information processing apparatus 100 illustrated in FIG. 10 is illustrated in FIG. 11 and FIG. 12. Referring to FIG. 11, in Operation S1, the input unit 110 acquires processing data from another computer or accepts data input by the user and stores the data in the first data storage unit 120.

In Operation S3, the physical-quantity calculation unit 130 initializes a time t to zero. In Operation S5, the neighborhood list generator 131 generates a neighbor particle list for each particle based on the distribution of the particles at the time t and stores the neighbor particle list in the second data storage unit 140.

When t=0, the identifiers of other particles which are located within the influence radius 2 h from the initial position included in the data stored in the first data storage unit 120, for example, the target particle, are added to the list. The influence radius is a radius in which the particles influence each other and may be a radius in which a process, such as application of a force to the other particles, is performed, for example, when the particles move. When t>0, the neighbor particle list may be generated by using the data stored in the second data storage unit 140.

In Operation S7, the physical-quantity calculation unit 130 identifies one particle a that is not processed. In Operation S9, the physical-quantity calculation unit 130 calculates the target physical quantity of analysis (including the time differential of the internal energy based on the elements other than the radiative cooling) of the identified particle a in accordance with the physical model (for example, the equations (1) to (3)) of the continuum as superposition of interactions between the particle and the particles included in the neighbor particle list of the particle and stores the calculated target physical quantity of analysis in the second data storage unit 140. For example, the process disclosed in Non-Patent Document 2 may be performed in Operation S9.

The target physical quantity of analysis may include, for example, the acceleration, the velocity, the time differential of the density, or the time differential of the internal energy based on the elements other than the radiative cooling. The time differential of the internal energy based on the elements other than the radiative cooling is represented in the following manner:

$${\frac{d {u}_{a}}{d t} \vert}_{Non \text{-} radiative cooling}$$

In the above expression, uₐ denotes the internal energy of the particle a.

In Operation S11, the radiative cooling calculator 132 calculates the amount of the internal energy (the time differential of the internal energy) which is lost by the radiative cooling per unit time by using the correction coefficient gₐ corresponding to the degree of exposure to the surface of the object for the identified particle a and stores the calculated amount of the internal energy in the second data storage unit 140. For example, the time differential of the internal energy is calculated according to the equation (8) and the equation (9). The time differential of the internal energy based on the radiative cooling is represented in the following manner:

$${\frac{d {u}_{a}}{d t} \vert}_{Radiative cooling}$$

In Operation S13, the physical-quantity calculation unit 130 adds the calculated amount of the internal energy to the time differential of the internal energy and stores the result of the addition in the second data storage unit 140. For example, the following calculation may be performed:

$${{\frac{d {u}_{a}}{d t} = \frac{d {u}_{a}}{d t} \vert}_{Non \text{-} radiative cooling} + \frac{d {u}_{a}}{d t} \vert}_{Radiative cooling}$$

In Operation S15, the physical-quantity calculation unit 130 determines whether any particle that is not processed exists. If any particle that is not processed exists (YES in Operation S15), the process goes back to Operation S7. If no particle that is not processed exists (NO in Operation S15), the process goes to Operations in FIG. 12 via a terminal A.

Referring to FIG. 12, in Operation S17, the integration processor 133 in the physical-quantity calculation unit 130 performs the time integration of the target physical quantity of analysis for each particle and stores the result of the processing in the second data storage unit 140. The following calculation may be performed to the target internal energy:

$${u}_{a}^{t + Δ t} = {u}_{a}^{t} + \frac{d {u}_{a}}{d t} Δ t$$

In the above equation, u^{t}ₐ denotes the internal energy at the time t. /

Similar calculation may be performed to other target physical quantities of analysis to calculate the physical quantity at a time t+Δt for each particle.

In Operation S19, the output unit 150 outputs the physical quantity at the time t+Δt, which is stored in the second data storage unit 140, to an output apparatus, such as another computer, a printer apparatus, or a display apparatus.

In Operation S21, the physical-quantity calculation unit 130 determines whether, for example, the time t reaches a process end time to determine whether the process is to be terminated. If the physical-quantity calculation unit 130 determines that the process is to be terminated (YES in Operation S21), the process illustrated in FIG. 11 and FIG. 12 is terminated. If the physical-quantity calculation unit 130 determines that the process is not to be terminated (NO in Operation S21), in Operation S23, the physical-quantity calculation unit 130 increments the time t by Δt. Then, the process goes to Operation S5 via a terminal B.

The coefficient gₐ may have a value in which the state of each particle is reflected, for example, a value corresponding to the degree of exposure to the surface of the object through the above process. Even if each particle is in different states at different unit times, the time differentials of the internal energy based on the radiative cooling corresponding to the respective states may be calculated.

Since the correction coefficient gₐ is defined as the continuous function, instead of the branch in the processing flow, the effect of the radiative cooling may be reflected in a non-step manner to accurately calculate the variation in temperature of the object.

For example, the functional blocks illustrated in FIG. 10 may not be matched with a program module configuration. In the processing flow, for example, multiple processors may perform the parallel computing for the calculation of each particle.

The functions of the information processing apparatus 100 may be performed by multiple computers, instead of one computer.

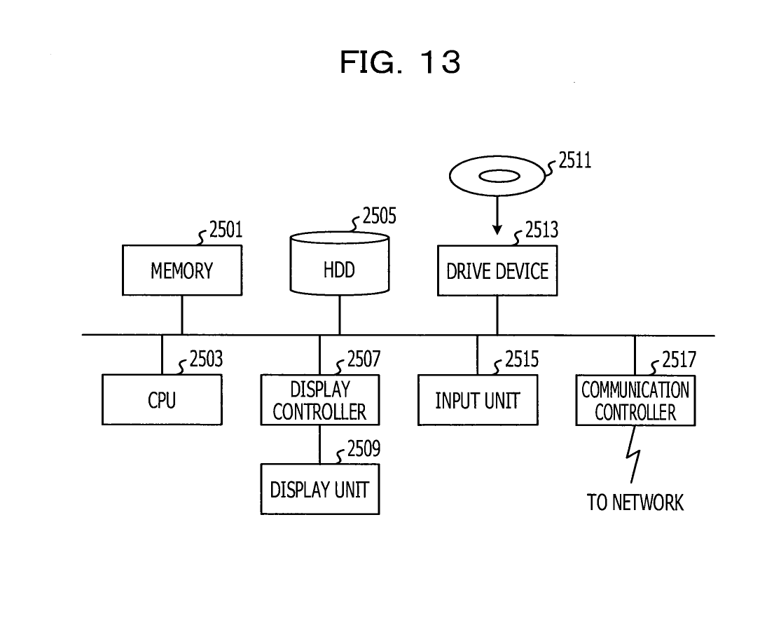

FIG. 13 illustrates an example of a computer. For example, the information processing apparatus 100 described above may be the computer apparatus illustrated in FIG. 13. Referring to FIG. 13, in the computer, a memory 2501, a central processing unit (CPU) 2503, a hard disk drive (HDD) 2505, a display controller 2507 connected to a display unit 2509, a drive device 13 for a removable disk 2511, an input unit 2515, and a communication controller 2517 for connection to a network are coupled to each other via a bus 2519. An operating system (OS) and an application program to execute the above processing, for example, the process illustrated in FIG. 11 and FIG. 12 are stored in the HDD 2505 and are read out from the HDD 2505 to be supplied to the memory 2501 in the execution by the CPU 2503. The CPU 2503 controls the display controller 2507, the communication controller 2517, or the drive device 2513 in accordance with the content of processing by the application program to cause the display controller 2507, the communication controller 2517, or the drive device 2513 to execute a certain operation. Data during processing may be stored in the memory 2501 or the HDD 2505. The application program to execute the above processing is stored in the computer-readable removable disk 2511 for distribution and is installed in the HDD 2505 from the drive device 2513. The application program may be installed in the HDD 2505 via a network, such as the Internet, and the communication controller 2517. In the computer apparatus, the variety of processing described above may be executed in cooperation with the hardware including the CPU 2503 and the memory 2501 and the programs including the OS and the application program.

In the numerical calculation method, (A) the time differential of the internal energy that corresponds to the coefficient corresponding to the degree of exposure of each particle to the surface of a continuum when the continuum is represented as a collection of particles and that is based on the radiative cooling is calculated and (B) the internal energy after the unit time is calculated based on the time differential of the internal energy calculated for each particle.

Accordingly, the state of each particle is reflected and the time differential of the internal energy based on the radiative cooling is calculated in accordance with the variation in the state.

The coefficient may be the continuous function to perform the correction, for example, so as to meet the following conditions: (a) the radiative cooling does not occur when the particles exist in the continuum, (b) the radiative cooling occurs from one face of a cube having a volume equivalent to that of the particles when the particles are uniformly distributed on the plain face, and (c) the radiative cooling occurs in the same manner as in a sphere having a volume equivalent to that of the particles when the particles are isolated.

The above correction may allow the time differential of the internal energy based on the radiative cooling to be accurately calculated.

The continuous function may be a function of the normalized number density sₐ:

$${s}_{a} = {\sum }_{b} \frac{{m}_{b}}{{ρ}_{b}} W ( {r}_{ab} , h )$$

In the above equation, b denotes each particle within a certain range of the particle a, m denotes the mass of the particle, p denotes the density, r_{ab} denotes the distance between the particle a and the particle b, h denotes a parameter representing the size of the influence domain of the particle, and W denotes the Kernel function. Since the normalized number density is varied with the particle b within the range of impact, the time differential of the internal energy based on the radiative cooling, which corresponds to the state of the particle a, is calculated.

The continuous function may be a polynomial of the following variable:

$${Q}_{a} = \frac{( 1 - {s}_{a} )}{( 1 - {s}_{min , a} )}$$

The conversion of the variable (s_{min,a}=mₐ/ρₐW(0,h) cilitate the setting of the conditions for the polynomial.

The continuous function may be the following:

$${g}_{a} ( {Q}_{a} ) = {A}_{a} ( {a}_{2 , a} {Q}_{a}^{2} + {a}_{3 , a} {Q}_{a}^{3} )$$

$${A}_{a} = {{S}_{1 , a} ( \frac{{m}_{a}}{{ρ}_{a}} )}^{- 1 + \frac{1}{d}} \\ {S}_{1 , a} = 4 π {r}_{a}^{2} \\ {r}_{a} = {( \frac{3}{4 π} \frac{{m}_{a}}{{ρ}_{a}} )}^{\frac{1}{3}} \\ {a}_{2 , a} = \frac{8}{{A}_{a}} - 1 \\ {a}_{3 , a} = 2 - \frac{8}{{A}_{a}}$$

The function gₐ(Qₐ) is a smooth continuous function that meets the condition corresponding to the three conditions (a) to (c) described above and the condition that the function is smooth around Qₐ=0 and that has the lowest order.

A program causing a computer to execute the above processing may be created. The program may be stored in a computer-readable storage medium, such as a flexible disk, an optical disk including a compact disk-read only memory (CD-ROM), a magneto-optical disk, a semiconductor memory (for example, a ROM), or a hard disk, or in a storage unit. The data during processing may be temporarily stored in a storage unit, such as a random access memory (RAM).

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An information processing method comprising:
calculating, by a computer, a time differential of internal energy that corresponds to a coefficient and is based on radiative cooling, the coefficient corresponding to a degree of exposure of each particle in a collection of particles to a surface of a continuum represented by the collection of the particles; and
calculating, by the computer, the internal energy after a unit time based on the time differential of the internal energy.

2. The information processing method according to claim 1,
wherein the coefficient is a continuous function to perform correction so that the radiative cooling does not occur when the particles exist in the continuum.

3. The information processing method according to claim 1,
wherein the coefficient is a continuous function to perform correction so that the radiative cooling occurs from one face, among six faces of a parallelepiped having a volume substantially equivalent to a volume of the particles and sides of the same length, when the particles are uniformly distributed on a plain face.

4. The information processing method according to claim 1,
wherein the coefficient is a continuous function to perform correction so that the radiative cooling occurs in the same manner as in a sphere having a volume equivalent to a volume of the particles when the particles are isolated.

5. The information processing method according to claim 1,
wherein the coefficient is a function of a normalized number density sₐ:
$${s}_{a} = {\sum }_{b} \frac{{m}_{b}}{{ρ}_{b}} W ( {r}_{ab} , h )$$
wherein b denotes each particle within a certain range of a particle a, m denotes a mass of the particle, p denotes a density, r_{ab} denotes a distance between the particle a and a particle b, h denotes a parameter representing a size of a range of impact of the particle, and W denotes a Kernel function.

6. The information processing method according to claim 1,
wherein the coefficient is represented by the following polynomial:
$${Q}_{a} = \frac{( 1 - {s}_{a} )}{( 1 - {s}_{min , a} )}$$
wherein s_{min,a}=mₐ/ρₐW(0,h).

7. The information processing method according to claim 1, wherein the coefficient is:
$${g}_{a} ( {Q}_{a} ) = {A}_{a} ( {a}_{2 , a} {Q}_{a}^{2} + {a}_{3 , a} {Q}_{a}^{3} )$$
$${A}_{a} = {{S}_{1 , a} ( \frac{{m}_{a}}{{ρ}_{a}} )}^{- 1 + \frac{1}{d}} \\ {S}_{1 , a} = 4 π {r}_{a}^{2} \\ {r}_{a} = {( \frac{3}{4 π} \frac{{m}_{a}}{{ρ}_{a}} )}^{\frac{1}{3}} \\ {a}_{2 , a} = \frac{8}{{A}_{a}} - 1 \\ {a}_{3 , a} = 2 - \frac{8}{{A}_{a}}$$

8. An information processing system comprising:
a memory configured to store a numerical calculation program; and
a central processing unit configured to execute the numerical calculation program,
wherein the program causes the central processing unit to execute:
calculating a time differential of internal energy that corresponds to a coefficient and is based on radiative cooling, the coefficient corresponding to a degree of exposure of each particle in a collection of particles to a surface of a continuum represented by the collection of the particles; and
calculating the internal energy after a unit time based on the time differential of the internal energy.

9. The information processing system according to claim 8,
wherein the coefficient is a continuous function to perform correction so that the radiative cooling does not occur when the particles exist in the continuum.

10. The information processing system according to claim 8,
wherein the coefficient is a continuous function to perform correction so that the radiative cooling occurs from one face, among six faces of a parallelepiped having a volume substantially equivalent to a volume of the particles and sides of the same length, when the particles are uniformly distributed on a plain face.

11. The information processing system according to claim 8,
wherein the coefficient is a continuous function to perform correction so that the radiative cooling occurs in the same manner as in a sphere having a volume equivalent to a volume of the particles when the particles are isolated.

12. The information processing system according to claim 8,
wherein the coefficient is a function of a normalized number density sₐ:
$${s}_{a} = {\sum }_{b} \frac{{m}_{b}}{{ρ}_{b}} W ( {r}_{ab} , h )$$
wherein b denotes each particle within a certain range of a particle a, m denotes a mass of the particle, p denotes a density, r_{ab} denotes a distance between the particle a and a particle b, h denotes a parameter representing a size of a range of impact of the particle, and W denotes a Kernel function.

13. The information processing system according to claim 8,
wherein the coefficient is represented by the following polynomial:
$${Q}_{a} = \frac{( 1 - {s}_{a} )}{( 1 - {s}_{min , a} )}$$
wherein s_{min,a}=mₐ/ρₐW(0,h).

14. The information processing system according to claim 8,
wherein the coefficient is:
$${g}_{a} ( {Q}_{a} ) = {A}_{a} ( {a}_{2 , a} {Q}_{a}^{2} + {a}_{3 , a} {Q}_{a}^{3} )$$
$${A}_{a} = {{S}_{1 , a} ( \frac{{m}_{a}}{{ρ}_{a}} )}^{- 1 + \frac{1}{d}} \\ {S}_{1 , a} = 4 π {r}_{a}^{2} \\ {r}_{a} = {( \frac{3}{4 π} \frac{{m}_{a}}{{ρ}_{a}} )}^{\frac{1}{3}} \\ {a}_{2 , a} = \frac{8}{{A}_{a}} - 1 \\ {a}_{3 , a} = 2 - \frac{8}{{A}_{a}}$$
